(19) United States
(12) Patent Application Publication
(10) Pub. No.: US 2026/0058087 A1
(43) Pub. Date: Feb. 26, 2026

(54) ION IMPLANTATION METHOD AND SOLID SOURCE MATERIAL USED FOR ION GENERATION

(71) Applicant: Sumitomo Heavy Industries Ion Technology Co., Ltd., Tokyo (JP)

(72) Inventors: Shiro NINOMIYA, Ehime (JP); Yoji KAWASAKI, Ehime (JP); Shuichi MAENO, Kyoto (JP)

(21) Appl. No.: 19/372,426

(22) Filed: Oct. 29, 2025

Related U.S. Application Data
(63) Continuation of application No. PCT/JP2024/028861, filed on Aug. 13, 2024.

(30) Foreign Application Priority Data
Aug. 24, 2023 (JP) 2023-136646

(51) Int. Cl. H01J 37/08; H01J 37/317

(52) U.S. Cl. CPC H01J 37/08; H01J 37/3171

(57) ABSTRACT

An ion implantation method includes heating a solid source material containing a first metal element at a predetermined operating temperature to generate a vapor containing the first metal element, generating a plasma containing ions of the first metal element using the vapor, and implanting the ions of the first metal element obtained from the plasma into a workpiece, in which the solid source material contains a first material that contains the first metal element and has a melting point, a sublimation point, or a decomposition point lower than the operating temperature, and a second material that contains an oxide, a nitride, a carbide, or a metal and has a melting point, a sublimation point, or a decomposition point higher than the operating temperature.

### CROSS-REFERENCE TO RELATED APPLICATIONS

This is a bypass continuation of International PCT Application No. PCT/JP2024/028861, filed on Aug. 13, 2024, which claims priority to Japanese Patent Application No. 2023-136646, filed on Aug. 24, 2023, which are incorporated by reference herein in their entirety.

### BACKGROUND

### Technical Field

Certain embodiments of the present disclosure relate to an ion implantation method, a solid source material used for ion generation, and an ion implanter.

### Description of Related Art

In a semiconductor manufacturing process, a process of implanting ions into a semiconductor wafer (also referred to as an ion implantation process) is typically performed for the purpose of changing the conductivity of a semiconductor, changing a crystal structure of the semiconductor, or the like. A device that is used in this process is generally referred to as an ion implanter. In the ion implanter, an ion generating device for generating a plasma from source gas to generate ions is used. As the source gas, a vapor that is generated by heating a solid source material containing a metal element may be used.

For example, in order to generate indium (In) ions, indium iodide having a melting point of 210° C. is heated at 300° C. to 500° C. and vaporized in a heating furnace. The indium iodide in the heating furnace is completely melted to enter a liquid state. Therefore, it is known that the liquefied indium iodide is stickily attached to a vapor introduction pipe or the like connecting the heating furnace and a plasma generating container to clog the vapor introduction pipe, which may inhibit stable generation of indium ions. Accordingly, there is proposed a method for using indium fluoride having a melting point of 1170° C. and heating the indium fluoride at 600° C. to 1170° C. that is lower than the melting point to prevent melting of a solid material and to stably generate indium ions (for example, refer to related art).

### SUMMARY

According to an embodiment of the present disclosure, there is provided an ion implantation method including: heating a solid source material containing a first metal element at a predetermined operating temperature to generate a vapor containing the first metal element; generating a plasma containing ions of the first metal element using the vapor; and implanting the ions of the first metal element obtained from the plasma into a workpiece. The solid source material contains a first material that contains the first metal element and has a melting point, a sublimation point, or a decomposition point lower than the operating temperature, and a second material that contains an oxide, a nitride, a carbide, or a metal and has a melting point, a sublimation point, or a decomposition point higher than the operating temperature.

According to another embodiment of the present disclosure, there is provided a solid source material. This solid source material is a solid source material that is heated at a predetermined operating temperature for generating ions of a first metal element to be implanted into a workpiece, the solid source material including: a first material that contains the first metal element and has a melting point, a sublimation point, or a decomposition point lower than the operating temperature, and a second material that contains an oxide, a nitride, a carbide, or a metal and has a melting point, a sublimation point, or a decomposition point higher than the operating temperature.

### BRIEF DESCRIPTION OF THE DRAWINGS

FIG. 1 is a functional block diagram illustrating an example of a schematic configuration of an ion implanter according to an embodiment.

FIG. 2 is a top view illustrating an example of a schematic configuration of an ion implanter according to the embodiment.

FIG. 3 is a side view illustrating the example of the schematic configuration of the ion implanter according to the embodiment.

FIG. 4 is a cross-sectional view schematically illustrating the configuration of the ion generating device according to the embodiment.

FIG. 5 is a table illustrating materials and operating temperatures of solid source materials in Comparative Example and Examples and obtained beam currents.

FIG. 6 is a graph illustrating a relationship between the operating temperatures and the beam currents in Comparative Example and Examples.

FIG. 7 is a flowchart illustrating an example of an ion implantation method according to the embodiment.

### DETAILED DESCRIPTION

When the solid source material containing a metal element is heated at a temperature lower than the melting point, there is a case where a sufficient vapor pressure cannot be obtained depending on the material, and the amount of metal ions generated cannot be increased. In this case, the beam current of a metal ion beam extracted from the ion generating device is restricted, which may limit productivity of ion implantation processing. In addition, when the solid source material containing a metal element is heated at a temperature higher than the melting point, stable generation of metal ions is inhibited by flowing, attachment, or the like of the liquefied source material.

It is desirable to provide a technique for stabilizing and increasing the amount of metal ions generated using a vapor obtained by heating a solid source material.

Any combination of the above-described components or a replacement of the components and expressions of the present disclosure between methods, devices, systems, and the like is also effective as an embodiment of the present disclosure.

Hereinafter, an embodiment for carrying out the present disclosure will be described in detail with reference to the drawings. In the description of the drawings, the same elements will be denoted by the same reference numerals and repeated description thereof will be omitted as appropriate. Further, a configuration described below is an example and does not limit the scope of the present disclosure.

The summary will be described before describing the embodiment in detail. The present embodiment relates to an ion implantation method. The ion implantation method includes: heating a solid source material containing a first metal element at a predetermined operating temperature to generate a vapor containing the first metal element; generating a plasma containing ions of the first metal element using the vapor; and implanting the ions of the first metal element obtained from the plasma into a workpiece. The solid source material is heated, for example, in a state where a vapor generating chamber is filled therewith, and the generated vapor is supplied to a plasma generating chamber through a vapor introduction pipe.

When the solid source material is heated to obtain the vapor, the heated solid source material may be softened, fluidized, liquefied, or sintered depending on the material of the solid source material. When the solid source material is fluidized or liquefied, the solid source material may move in the vapor generating chamber or the vapor introduction pipe due to the influence of gravity or capillarity. When the heating of the solid source material is stopped, the source material that is moved due to the fluidization or the liquefaction may be fixed in the vapor generating chamber or the vapor introduction pipe. In addition, the sintering of the source material may also cause fixing. When fixing occurs, the workability of maintenance such as replacement or refilling of the source material decreases. In addition, when the source material in the vapor generating chamber or the vapor introduction pipe is clogged, the amount of the vapor generated may be unstable. In addition, as compared to before heating, the shape or surface area of the entire source material may change such that the amount of the vapor generated also varies. When the amount of the vapor generated is unstable, the formation of the plasma generated using the vapor is unstable, and the amount of the ions extracted from the plasma may be unstable.

The solid source material with which the vapor generating chamber is filled is not constantly operated under the same condition, and may be operated under different conditions depending on conditions of the ion implantation processing in order to acquire a desired ion species with a desired beam current. Therefore, the heating temperature of the vapor generating chamber may change depending on conditions. In addition, in order to switch between ion species, an operation state where the vapor generating chamber is heated and a non-operation state where the vapor generating chamber is not heated may also be repeated. In this case, a state change such as softening, fluidization, liquefaction, or sintering is repeated such that the shape or surface area of the solid source material changes significantly, which may cause instability of the amount of the vapor generated.

In the present embodiment, a solid source material containing a first material and a second material is used. The first material contains the first metal element and has a melting point, a sublimation point, or a decomposition point lower than the operating temperature. The second material contains an oxide, a nitride, a carbide, or a metal and has a melting point, a sublimation point, or a decomposition point higher than the operating temperature. In the present embodiment, by using the first material having a melting point, a sublimation point, or a decomposition point lower than the operating temperature, the vapor pressure of the vapor containing the first metal element can be increased, and the amount of the ions of the first metal element generated can be increased. In addition, by using the second material having a melting point, a sublimation point, or a decomposition point higher than the operating temperature as the solid source material in combination, the first material that is softened or liquefied by heating can be held by the second material, and a state change such as fluidization, liquefaction, or sintering can be suppressed. For example, outflow of the liquefied first material to the outside of the vapor generating chamber or fixing thereof to an unintended position can be suppressed, and the amount of the ions of the first metal element generated can be stabilized.

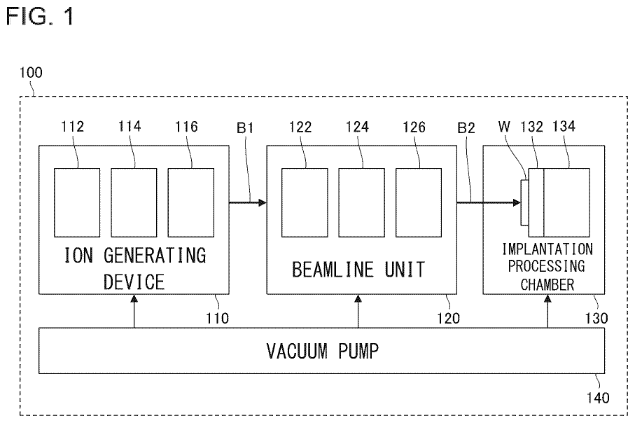

FIG. 1 is a functional block diagram illustrating an example of a schematic configuration of an ion implanter 100 according to the embodiment. The ion implanter 100 includes an ion generating device 110, a beamline unit 120, an implantation processing chamber 130, and a vacuum pump 140.

The ion generating device 110 generates an ion beam to be implanted into a semiconductor wafer W. The ion generating device 110 includes an ion source 112, an extraction electrode 114, and a mass analyzer 116. The ion source 112 causes arc discharge to occur in an internal space of an arc chamber such that atoms or molecules of source gas introduced into the internal space of the arc chamber are ionized to generate ions. The extraction electrode 114 generates an ion beam by extracting the ions generated in the internal space of the arc chamber to the outside of the arc chamber as an ion cluster in the form of a beam. In the extraction electrode 114, for example, a negative extraction voltage is applied to the arc chamber, and the ions are accelerated by the extraction voltage to form an ion beam. The mass analyzer 116 applies and deflects a magnetic field to the ion beam extracted by the extraction electrode 114 to select only a desired ion species. An ion beam B1 that is configured with the ion cluster of the desired ion species is provided to the subsequent beamline unit 120. The ion beam B1 provided from the ion generating device 110 to the beamline unit 120 will also be referred to as “first ion beam”. The beam current of the first ion beam B1 is, for example, 0.1 mA or more and 20 mA or less, for example, 0.5 mA or more and 10 mA or less, or, for example, 1 mA or more.

The beamline unit 120 transports the first ion beam B1 provided from the ion generating device 110 toward the implantation processing chamber 130. The beamline unit 120 applies at least one of an electric field and a magnetic field to the first ion beam B1 to perform at least one of deflection, acceleration, deceleration, shaping, and scanning for the first ion beam B1 to generate a second ion beam B2. The beamline unit 120 includes, for example, a beam shaping unit 122 that is configured with a quadrupole lens unit or the like for shaping the first ion beam B1, a beam scan unit 124 that performs a reciprocating scan using the first ion beam B1 in a first direction, and a beam parallelizing unit 126 that parallelize the first ion beam B1 used for the reciprocating scan in the first direction. For example, the beamline unit 120 provides the scanned beam that is used for the reciprocating scan in the first direction to the subsequent implantation processing chamber 130. The ion beam B2 provided from the beamline unit 120 to the implantation processing chamber 130 will also be referred to as “second ion beam”. The energy of the second ion beam B2 is, for example, 0.2 eV or more and 1 MeV or less or, for example, 10 keV or more and 100 keV or less.

The beamline unit 120 may include a ribbon beam generating unit instead of the beam scan unit 124. The ribbon beam generation unit applies at least one of an electric field and a magnetic field to the first ion beam B1 and spreads the beam size in the first direction to generate a ribbon beam that is shaped in a ribbon shape. In this case, for example, the beamline unit 120 provides the ribbon beam of which the beam size is spread in the first direction to the subsequent implantation processing chamber 130.

The implantation processing chamber 130 accommodates a workpiece (for example, a semiconductor wafer) W to be irradiated with the second ion beam B2. The implantation processing chamber 130 includes a holder 132 that holds the workpiece W. The implantation processing chamber 130 may include a drive mechanism 134 that reciprocates the holder 132 in a second direction. For example, the second ion beam B2 that is used for the reciprocating scan in the first direction (for example, a width direction or a horizontal direction of the workpiece W) in the beamline unit 120 is emitted to the workpiece W that is reciprocated in the second direction in the second direction (a height direction or a vertical direction of the workpiece W) in the implantation processing chamber 130. The entire surface of the workpiece W is irradiated with the ion beam B2 by hybrid scan where the above-described beam scan and mechanical scan are combined. Instead, the second ion beam B2 that is spread in a ribbon shape in the first direction by the beamline unit 120 may be emitted to the workpiece W that is reciprocated in the second direction in the implantation processing chamber 130.

The vacuum pump 140 includes a vacuum evacuation system for providing a desired vacuum environment to the ion generating device 110, the beamline unit 120, and the implantation processing chamber 130. The vacuum pump 140 provides the vacuum environment to each of the ion generating device 110, the beamline unit 120, and the implantation processing chamber 130 during the ion implantation processing of irradiating the workpiece with the ion beam. The vacuum environments respectively provided to the ion generating device 110, the beamline unit 120, and the implantation processing chamber 130 may be common or different from each other.

The ion implanter 100 may have a configuration not including a part of the functional blocks illustrated in FIG. 1. For example, the ion implanter 100 does not need to include the beamline unit 120. In this case, the first ion beam B1 that is generated by the ion generating device 110 is emitted to the workpiece W held in the implantation processing chamber 130 as it is.

The ion implanter 100 may have a configuration further including functional blocks not illustrated in FIG. 1. For example, the ion implanter 100 may further include an acceleration/deceleration unit that accelerates or decelerates the first ion beam B1 to adjust the energy of the first ion beam B1. The acceleration/deceleration unit can be provided, for example, between the ion generating device 110 and the beamline unit 120. The acceleration/deceleration unit may include a plurality of acceleration/deceleration electrodes that applies an electrostatic field to the ion beam, or may be a linear acceleration unit that applies a radio frequency electric field to the ion beam.

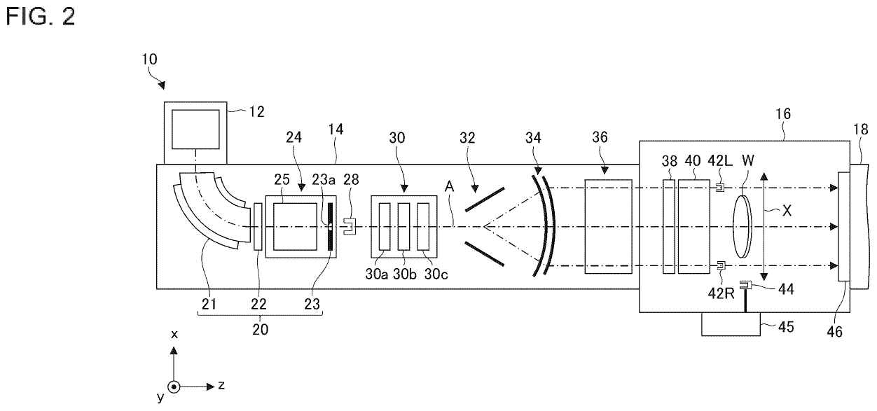

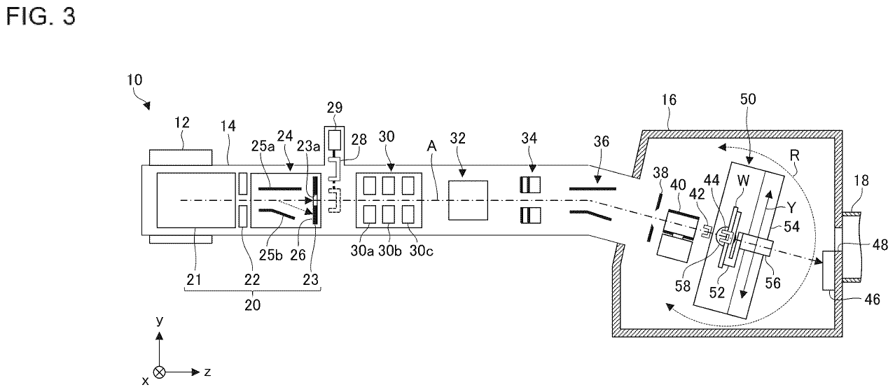

FIG. 2 is a top view illustrating the example of a schematic configuration of an ion implanter 10 according to the embodiment. FIG. 3 is a side view illustrating the example of the schematic configuration of the ion implanter 10 according to the embodiment. The ion implanter 10 is configured to perform ion implantation processing on the surface of the workpieces W. The workpiece W is, for example, a substrate, and is, for example, a semiconductor wafer. For convenience of description, the workpiece W may be referred to as a “wafer W” in the description herein. However, this is not intended to limit an implantation processing target to a specific object.

The ion implanter 10 is configured to irradiate a whole processing surface of the wafer W with a beam by performing a reciprocating scan using the ion beam in one direction and reciprocating the wafer W in a direction perpendicular to a scanning direction. In the description herein, for convenience of description, a traveling direction of the ion beam traveling along a designed beamline A is defined as a z-direction, and a plane perpendicular to the z-direction is defined as an xy-plane. When the workpiece W is scanned with the ion beam, the scanning direction of the beam is defined as an x-direction, and a direction perpendicular to the z-direction and the x-direction is defined as a y-direction. Accordingly, the reciprocating scan using the beam is performed in the x-direction, and a reciprocating movement of the wafer W is performed in the y-direction.

The ion implanter 10 includes an ion generating device 12, a beamline unit 14, and an implantation processing chamber 16. The ion implanter 10 may further include a wafer transport unit 18. The ion generating device 12 is configured to provide an ion beam for the beamline unit 14. The beamline unit 14 is configured to transport the ion beam from the ion generating device 12 to the implantation processing chamber 16. The wafer W to be implanted is accommodated in the implantation processing chamber 16, and the implantation processing of irradiating the wafer W with the ion beam provided from the beamline unit 14 is performed. The wafer transport unit 18 is configured to transport an unprocessed wafer before ion implantation processing into the implantation processing chamber 16 and transports a processed wafer after the ion implantation processing out of the implantation processing chamber 16. The ion implanter 10 includes a vacuum evacuation system (not shown) for providing a desired vacuum environment to the ion generating device 12, the beamline unit 14, the implantation processing chamber 16, and the wafer transport unit 18.

The beamline unit 14 includes a mass analyzer 20, a beam park unit 24, a beam shaping unit 30, a beam scan unit 32, a beam parallelizing unit 34, and an angular energy filter (AEF) 36, in order from the upstream side of a beamline A. The upstream of the beamline A means a side closer to the ion generating device 12, and the downstream of the beamline A means a side closer to the implantation processing chamber 16 (or a beam stopper 46).

The mass analyzer 20 is provided downstream of the ion generating device 12, and is configured to select a required ion species from the ion beam extracted from the ion generating device 12 by performing mass analysis. The mass analyzer 20 includes a mass analyzing magnet 21, a mass analyzing lens 22, and a mass resolving aperture 23.

The mass analyzing magnet 21 applies a magnetic field to the ion beam extracted from the ion generating device 12, and deflects the ion beam into different paths in accordance with a value of a mass-to-charge ratio M=m/q (m is mass, and q is charge) of the ions. For example, the mass analyzing magnet 21 applies the magnetic field in the y-direction (−y-direction in FIGS. 2 and 3) to the ion beam such that the ion beam is deflected in the x-direction. The magnetic field intensity of the mass analyzing magnet 21 is adjusted such that the ion species having a desired mass-to-charge ratio M passes through the mass resolving aperture 23.

The mass analyzing lens 22 is provided downstream of the mass analyzing magnet 21, and is configured to adjust focusing/defocusing power for the ion beam. The mass analyzing lens 22 adjusts a focusing position of the ion beam passing through the mass resolving aperture 23 in the beam traveling direction (z-direction), and adjusts a mass resolution M/dM of the mass analyzer 20. The mass analyzing lens 22 is not an essential configuration, and the mass analyzer 20 does not include the mass analyzing lens 22.

The mass resolving aperture 23 is provided downstream of the mass analyzing lens 22, and is provided at a position away from the mass analyzing lens 22. The mass resolving aperture 23 is configured such that a beam deflection direction (x-direction) of the mass analyzing magnet 21 coincides with an aperture width, and has an opening 23a having a shape which is relatively short in the x-direction and relatively long in the y-direction.

The mass resolving aperture 23 may be configured such that the aperture width is variable for adjusting the mass resolution. The mass resolving aperture 23 may be configured to include two shield members that are movable in an aperture width direction, and may be configured such that the aperture width is adjustable by changing an interval between the two shield members. The mass resolving aperture 23 may be configured such that the aperture width is variable by switching the mass resolving aperture 23 with any one of a plurality of slits having different aperture widths.

The beam park unit 24 is configured to cause the ion beam to temporarily retreat from the beamline A and to block the ion beam directed to the implantation processing chamber 16 (or the wafer W) located downstream. The beam park unit 24 can be disposed at any position in an intermediate portion of the beamline A. For example, the beam park unit 24 can be disposed between the mass analyzing lens 22 and the mass resolving aperture 23. A prescribed distance is required between the mass analyzing lens 22 and the mass resolving aperture 23. Therefore, the beam park unit 24 is disposed between both of these. In this manner, a length of the beamline A can be shortened, compared to a case where the beam park unit 24 is disposed at other positions. Therefore, the whole ion implanter 10 can be reduced in size.

The beam park unit 24 includes a pair of park electrodes 25 (25a and 25b) and a beam dump 26. The pair of park electrodes 25a and 25b faces each other across the beamline A, and faces in a direction (y-direction) perpendicular to the beam deflection direction (x-direction) of the mass analyzing magnet 21. The beam dump 26 is provided on the downstream side of the park electrodes 25a and 25b on the beamline A, and is provided away from the beamline A in a facing direction of the park electrodes 25a and 25b.

The first park electrode 25a is disposed on an upper side of the beamline A in a direction of gravity, and the second park electrode 25b is disposed on a lower side of the beamline A in the direction of gravity. The beam dump 26 is provided at a position away from the beamline A toward the lower side in the direction of gravity, and is disposed on the lower side of the opening 23a of the mass resolving aperture 23 in the direction of gravity. For example, the beam dump 26 is configured to include a portion where the opening 23a of the mass resolving aperture 23 is not formed. The beam dump 26 may be configured to be separate from the mass resolving aperture 23.

The beam park unit 24 deflects the ion beam by using an electric field applied between the pair of park electrodes 25a and 25b, and causes the ion beam to retreat from the beamline A. For example, a negative voltage is applied to the second park electrode 25b, based on a potential of the first park electrode 25a. In this manner, the ion beam is deflected downward from the beamline A in the direction of gravity, and is incident into the beam dump 26. In FIG. 3, a trajectory of the ion beam directed toward the beam dump 26 is indicated by a broken line. In addition, the beam park unit 24 causes the ion beam to pass through the downstream side along the beamline A by setting the pair of park electrodes 25a and 25b to have the same potential. The beam park unit 24 is configured to be operable by switching between a first mode in which the ion beam passes through the downstream side and a second mode in which the ion beam is incident into the beam dump 26.

An injector Faraday cup 28 is provided downstream of the mass resolving aperture 23. The injector Faraday cup 28 is configured to be movable into and out of the beamline A by an operation of an injector drive unit 29. The injector drive unit 29 moves the injector Faraday cup 28 in a direction (for example, the y-direction) perpendicular to an extending direction of the beamline A. When the injector Faraday cup 28 is disposed on the beamline A as indicated by a broken line in FIG. 3, the injector Faraday cup 28 blocks the ion beam directed toward the downstream side. On the other hand, as indicated by a solid line in FIG. 3, when the injector Faraday cup 28 is removed from the beamline A, the blocking of the ion beam directed toward the downstream side is released.

The injector Faraday cup 28 is configured to measure a beam current of the ion beam on which the mass analysis is performed by the mass analyzer 20. The injector Faraday cup 28 can measure a mass spectrum of the ion beam by measuring the beam current while changing the magnetic field intensity of the mass analyzing magnet 21. The mass resolution of the mass analyzer 20 can be calculated using the measured mass spectrum.

The beam shaping unit 30 includes a focusing/defocusing unit such as a focusing/defocusing quadrupole lens (Q-lens), and is configured to shape the ion beam, which has passed through the mass analyzer 20, such that the ion beam has a desired cross-sectional shape. For example, the beam shaping unit 30 is configured to include an electric field type three-stage quadrupole lens (also referred to as a triplet Q-lens), and has three quadrupole lenses 30a, 30b, and 30c. The beam shaping unit 30 adopts the three lens units 30a to 30c. Accordingly, the beam shaping unit 30 can independently adjust the ion beam to focus or defocus in each of the x-direction and the y-direction. The beam shaping unit 30 may include a magnetic field type lens unit, or may include a lens unit that shapes the beam by using both an electric field and a magnetic field.

The beam scan unit 32 is a beam deflection unit configured to provide reciprocating scan using the beam and to perform scanning using the shaped ion beam in the x-direction. The beam scan unit 32 includes a pair of scanning electrodes facing each other in the beam scanning direction (x-direction). The pair of scanning electrodes is connected to a variable voltage power supply (not shown), and periodically changes a voltage applied between the pair of scanning electrodes. In this manner, an electric field generated between the electrodes is changed such that the ion beam is deflected at various angles. As a result, a whole scanning range is scanned with the ion beam in the x-direction. In FIG. 2, the scanning direction and the scanning range of the beam are indicated by an arrow X, and a plurality of trajectories of the ion beam in the scanning range are indicated by a one dot chain line.

The beam parallelizing unit 34 is configured such that the traveling direction of the ion beam used for the scanning is parallel to the trajectory of the designed beamline A. The beam parallelizing unit 34 has a plurality of arc-shaped parallelizing lens electrodes in which an ion beam passing slit is provided in a central portion in the y-direction. The parallelizing lens electrode is connected to a high-voltage power supply (not shown), and applies an electric field generated by voltage application to the ion beam such that the traveling directions of the ion beams are parallelized. The beam parallelizing unit 34 may be replaced with another beam parallelizing unit, and the beam parallelizing unit may be configured to serve as a magnet unit using a magnetic field.

An acceleration/deceleration (AD) column (not shown) for accelerating or decelerating the ion beam may be provided downstream of the beam parallelizing unit 34. The AD column is an acceleration/deceleration unit that applies an electrostatic field to the ion beam to accelerate or decelerate the ion beam.

The angular energy filter (AEF) 36 is configured to analyze energy of the ion beam, to deflect ions having necessary energy downward, and to guide the ions to the implantation processing chamber 16. The angular energy filter 36 includes a pair of AEF electrodes for electric field deflection. The pair of AEF electrodes is connected to a high-voltage power supply (not shown). In FIG. 3, the ion beam is deflected downward by applying a positive voltage to the upper AEF electrode and applying a negative voltage to the lower AEF electrode. The angular energy filter 36 may be configured by a magnetic device for deflection by a magnetic field or may be configured in combination with the pair of AEF electrodes for electric field deflection and the magnetic device for deflection by a magnetic field.

In this way, the beamline unit 14 supplies the ion beam to be emitted to the wafer W to the implantation processing chamber 16.

The implantation processing chamber 16 includes an energy defining slit 38, a plasma shower unit 40, a side cup 42, a center cup 44, and a beam stopper 46, in order from the upstream side of the beamline A. As illustrated in FIG. 3, the implantation processing chamber 16 includes a platen drive unit 50 that holds one or a plurality of wafers W.

The energy defining slit 38 is provided on the downstream side of the angular energy filter 36, and analyzes the energy of the ion beam incident into the wafer W together with the angular energy filter 36. The energy defining slit 38 is an energy defining slit (EDS) configured to include a slit that is horizontally long in the beam scanning direction (x-direction). The energy defining slit 38 causes the ion beam having a desired energy value or a desired energy range to pass through the wafer W, and blocks other ion beams.

The plasma shower unit 40 is positioned downstream side of the energy defining slit 38. The plasma shower unit 40 supplies low-energy electrons to the ion beam and the surface (wafer processing surfaces) of the wafer W in accordance with the beam current of the ion beam to suppress charge-up that is caused by the accumulation of positive charges on the wafer processing surface occurring due to ion implantation. For example, the plasma shower unit 40 includes a shower tube through which the ion beam passes, and a plasma generating device that supplies electrons into the shower tube.

The side cup 42 (42L and 42R) is configured to measure the beam current of the ion beam during the ion implantation processing into the wafer W. As illustrated in FIG. 3, the side cups 42R and 42L are disposed to be deviated to the right and left (the x-direction) from the wafer W disposed on the beamline A and are disposed at positions that do not block the ion beam directed toward the wafer W during the ion implantation. The ion beam is used in scanning in the x-direction beyond a range where the wafer W is positioned. Accordingly, a part of the beam used in scanning is incident into the side cups 42R and 42L even during the ion implantation. As a result, the beam current during the ion implantation processing is measured by the side cups 42R and 42L.

The center cup 44 is configured to measure a beam current on the wafer processing surface. The center cup 44 is configured to be movable by an operation of a drive unit 45, retreats from an implantation position where the wafer W is positioned during the ion implantation, and is inserted into the implantation position when the wafer W is not positioned at the implantation position. The center cup 44 measures the beam current while moving in the x-direction. In this manner, the center cup 44 can measure the beam current over the whole beam scanning range in the x-direction. In the center cup 44, a plurality of Faraday cups may be aligned in the x-direction to be formed in an array shape such that the beam currents can be simultaneously measured at a plurality of positions in the beam scanning direction (x-direction).

At least one of the side cup 42 and the center cup 44 may include a single Faraday cup for measuring the beam current, or may include an angle measurement device for measuring angle information of the beam. For example, the angle measurement device includes a slit and a plurality of current detectors provided away from the slit in the beam traveling direction (z-direction). For example, the angle measurement device can measure an angle component of the beam in the aperture width direction by causing the plurality of current detectors aligned in the aperture width direction to measure the beams passing through the slit. At least one of the side cup 42 and the center cup 44 may include a first angle measurement unit capable of measuring angle information in the x-direction and a second angle measurement unit capable of measuring angle information in the y-direction.

The platen drive unit 50 includes a wafer holding unit 52, a reciprocating mechanism 54, a twist angle adjustment mechanism 56, and a tilt angle adjustment mechanism 58. The wafer holding unit 52 includes an electrostatic chuck or the like for holding the wafer W. The reciprocating mechanism 54 reciprocates the wafer W held by the wafer holding unit 52 in the y-direction by reciprocating the wafer holding unit 52 in the reciprocating direction (y-direction) perpendicular to the beam scanning direction (x-direction). In FIG. 3, the reciprocating movement of the wafer W is indicated by an arrow Y as an example.

The twist angle adjustment mechanism 56 is a mechanism for adjusting a rotation angle of the wafer W, and rotates the wafer W around a normal line of the wafer processing surface as an axis to adjust a twist angle between an alignment mark provided in an outer peripheral portion of the wafer and a reference position. Here, the alignment mark of the wafer refers to, for example, a notch or an orientation flat that is provided on the outer peripheral portion of the wafer, and refers to a mark serving as a reference for an angular position in a crystal axis direction or a circumferential direction of the wafer. The twist angle adjustment mechanism 56 is provided between the wafer holding unit 52 and the reciprocating mechanism 54 and is reciprocated together with the wafer holding unit 52.

The tilt angle adjustment mechanism 58 adjusts tilting of the wafer W, and adjusts a tilt angle between the traveling direction of the ion beam directed toward the wafer processing surface and the normal line of the wafer processing surface. In the present embodiment, in the tilt angle of the wafer W, an angle at which the axis in the x-direction is a rotation center axis is adjusted as the tilt angle. The tilt angle adjustment mechanism 58 is provided between the reciprocating mechanism 54 and an inner wall of the implantation processing chamber 16, and is configured to adjust the tilt angle of the wafer W by rotating the entire platen drive unit 50 including the reciprocating mechanism 54 in an R-direction.

The platen drive unit 50 holds the wafer W such that the wafer W is movable between an implantation position where the wafer W is irradiated with an ion beam and a transport position where the wafer W is transported into or out of the wafer transport unit 18. FIG. 3 illustrates a state where the wafer W is at the implantation position, and the platen drive unit 50 holds the wafer W such that the wafer W intersects with the beamline A. The transport position of the wafer W corresponds to the position of the wafer holding unit 52 when a transport mechanism or a transport robot provided in the wafer transport unit 18 transports the wafer W into or out of a transport port 48.

The beam stopper 46 is provided at the most downstream of the beamline A, and is attached to, for example, the inner wall of the implantation processing chamber 16. When the wafer W does not exist on the beamline A, the ion beam is incident into the beam stopper 46. The beam stopper 46 is positioned close to the transport port 48 that connects the implantation processing chamber 16 and the wafer transport unit 18 to each other, and is provided at a position vertically below the transport port 48.

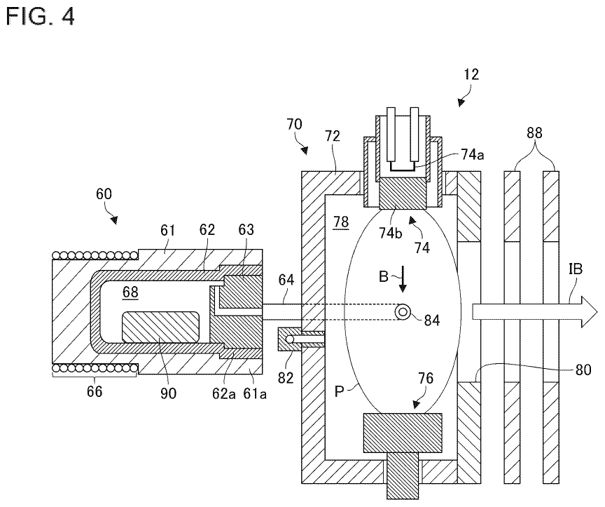

FIG. 4 is a cross-sectional view schematically illustrating the configuration of the ion generating device 12 according to the embodiment. The ion generating device 12 includes a vapor generating device 60 and a plasma generating device 70. The vapor generating device 60 generates a vapor containing a specific element that is a source material of ions configuring an ion beam IB, and supplies the generated vapor to the plasma generating device 70. The plasma generating device 70 ionizes the specific element in the vapor supplied from the vapor generating device 60, and generates a plasma P containing ions of the specific element. The ions generated by the plasma generating device 70 are extracted as the ion beam IB by the extraction electrode 88.

The vapor generating device 60 includes an outer container 61, an inner container 62, a lid 63, and a heating wire 66. The outer container 61 and the inner container 62 partition a vapor generating chamber 68 for heating a solid source material 90 to generate a vapor. The outer container 61 and the inner container 62 have a cylindrical double structure, and the inner container 62 is fitted into the outer container 61. The lid 63 is attached to an open end 62a of the inner container 62, and is configured to block the vapor generating chamber 68. A vapor introduction pipe 64 is provided in the lid 63. The vapor introduction pipe 64 guides the vapor generated in the vapor generating chamber 68 to the plasma generating device 70.

The inner container 62 is attachable to and detachable from the outer container 61. For example, a male thread is formed on an outer peripheral surface of the open end 62a of the inner container 62, a female thread is formed on an inner peripheral surface of an open end 61a of the outer container 61, and these threaded structures engage with each other. The lid 63 is attachable to and detachable from the inner container 62. For example, a female thread is formed on an inner peripheral surface of the open end 62a of the inner container 62, a male thread is formed on an outer peripheral surface of the lid 63, and these threaded structures engage with each other.

The outer container 61 is configured with, for example, a metal material such as stainless steel. The inner container 62 and the lid 63 are configured with, for example, graphite. The inner container 62 and the lid 63 may be made of a ceramic such as aluminum oxide, aluminum nitride, silicon oxide, silicon nitride, or silicon carbide, or a mixture thereof. The inner container 62 functions as a liner configuring an inner surface in contact with the solid source material 90 in the vapor generating chamber 68.

The heating wire 66 is provided on the outside of the outer container 61, and is wound around, for example, an outer peripheral surface of the outer container 61. By causing a current to flow through the heating wire 66, the outer container 61 is heated, and the inner container 62 is heated due to an increase in the temperature of the outer container 61. As a result, the vapor generating chamber 68 is heated at an operating temperature of about 100° C. to 1200° C. The operating temperature is adjusted depending on the material of the solid source material 90 or a necessary amount of vapor generated. A part of the solid source material 90 heated in the vapor generating chamber 68 is vaporized to generate a vapor and supplied to the plasma generating device 70 through the vapor introduction pipe 64.

The plasma generating device 70 includes an arc chamber 72, a cathode 74, and a repeller 76. The arc chamber 72 has a substantially rectangular parallelepiped box shape. The arc chamber 72 partitions a plasma generating chamber 78 where the plasma P is generated. A slit 80 for extracting the ion beam IB is provided on a front surface of the arc chamber 72. The slit 80 has an elongated shape extending in a direction from the cathode 74 toward the repeller 76.

The cathode 74 discharges thermal electrons to the plasma generating chamber 78. The cathode 74 is a so-called indirectly-heated cathode (IHC), and includes a filament 74a and a cathode head 74b. The cathode head 74b is heated by primary thermal electrons generated by the filament 74a, and supplies secondary thermal electrons to the plasma generating chamber 78. The cathode 74 may be a so-called directly-heated cathode.

The repeller 76 is provided at a position facing the cathode 74. The repeller 76 repels electrons supplied to the plasma generating chamber 78, and causes the electrons to stay in the plasma generating chamber 78 to improve the plasma generation efficiency.

A gas introduction port 82 and a vapor introduction port 84 are provided on a side wall of the arc chamber 72. The gas introduction port 82 supplies assist gas from a gas cylinder or the like not illustrated to the plasma generating chamber 78. The gas introduction port 82 is provided, for example, at a position opposite to the slit 80 with respect to the plasma generating chamber 78. The vapor introduction port 84 supplies the vapor generated by the vapor generating device 60 to the plasma generating chamber 78. The vapor introduction port 84 is provided, for example, at a side wall of the arc chamber 72 different from the side wall where the slit 80 or the gas introduction port 82 is provided.

In the plasma generating chamber 78, a magnetic field B is applied in a direction from the cathode 74 toward the repeller 76. The electrons supplied to the plasma generating chamber 78 are bound by the magnetic field B applied to the plasma generating chamber 78 and helically move along the magnetic field B. In the plasma generating chamber 78, the electrons helically move such that the plasma generation efficiency can be improved.

In the present embodiment, the ion generating device 12 is used, for example, for generating a gallium (Ga) ion beam IB. When the gallium ion beam is generated, in the related art, any solid material such as metal gallium (for example, pure gallium) or gallium oxide (for example, Ga₂O₃) is used alone as the source material. The melting point of the metal gallium is 30° C. Therefore, when heated at a temperature of 100° C. or higher in order to obtain a sufficient vapor pressure, the metal gallium is liquefied to flow in the vapor generating chamber 68. When the liquid metal gallium is solidified by stopping the heating, the threaded structure of the inner container 62 or the lid 63 is fixed such that it may be difficult to open the lid 63 or the vapor introduction pipe 64 may be clogged. On the other hand, the melting point of the gallium oxide is 1740° C. Therefore, even when the gallium oxide is heated at a high temperature of 1000° C. to 1200° C., softening or liquefaction does not occur, which does not cause fixing or clogging. However, as compared to a case where the metal gallium is used, the obtained beam current is lower, and heating at a high temperature of 1100° C. or higher is necessary for increasing the beam current.

In the present embodiment, the solid source material 90 containing the first material and the second material is used instead of using a single solid material. The first material contains the first metal element (for example, Ga) and has a melting point, a sublimation point, or a decomposition point lower than the predetermined operating temperature (for example, 100° C. to 1200° C.). Examples of the first material include metal gallium (for example, pure gallium, melting point 30° C.). The second material contains an oxide, a nitride, a carbide, or a metal and has a melting point, a sublimation point, or a decomposition point higher than the predetermined operating temperature (for example, 100° C. to 1200° C.). Examples of the second material include gallium oxide (for example, Ga₂O₃, melting point 1740° C.) and aluminum oxide (for example, Al₂O₃, melting point 2072° C.).

In the present embodiment, as the first material or the second material, a source material having a purity (for example, weight ratio) of 90% or more, 95% or more, 99% or more, or 99.9% or more can be used. In the present embodiment, a simple substance, a pure substance, or a pure metal of a specific element may represent that the purity (for example, weight ratio) of the specific element is 90% or more, 95% or more, 99% or more, or 99.9% or more.

The solid source material 90 may include a green compact obtained by compression-molding a powder where the first material and the second material are mixed. For example, a powder of the first material and a powder of the second material are prepared, a powder where both of the powders are mixed is produced, and a pressure is applied to the mixed powder to be molded into a pellet form. The molding pressure is not particularly limited and is, for example, 10 MPa or more and 1000 MPa or less, for example, 20 MPa or more and 500 MPa or less, or, for example, 50 MPa or more and 200 MPa or less. During or before compression molding, the powder of the first material or the second material may be cooled to a temperature of room temperature (for example, 20° C.) or lower. The average particle size of the powder of the first material or the second material is not particularly limited and is, for example, 0.1 μm or more and 2 mm or less, for example, 1 μm or more and 1 mm or less, or for example, 10 μm or more and 100 μm or less. The size of the molded green compact is not particularly limited and is, for example, 1 mm or more and 50 mm or less, or for example, 5 mm or more and 20 mm or less. The shape of the molded green compact is not particularly limited and may be, for example, a columnar shape, a disk shape, a spherical shape, an ellipsoidal shape, a cubic shape, a rectangular parallelepiped shape, a tablet shape, or an indefinite shape. The solid source material 90 may include only one piece of green compact or multiple pieces of green compact. A ratio W2/W1 between a first weight W1 of the first material and a second weight W2 of the second material in the solid source material 90 is, for example, 0.1 or more and 10 or less, for example, 0.2 or more and 5 or less, or for example, 0.5 or more and 2 or less.

When the solid source material 90 is heated at the predetermined operating temperature, the shape of the solid source material 90 that is a mixture of the first material and the second material does not substantially change, and the shape before heating can be maintained. The reason for this is as follows. Since the second material having a melting point, a sublimation point, or a decomposition point higher than the predetermined operating temperature is maintained in a solid state, the softened or liquefied first material is held by the second material that is maintained in a solid state, and the flow of the first material is restricted. As a result, while suppressing the flow of the first material caused by heating, the vapor pressure of the vapor containing the first metal element can be increased due to the heating of the first material having a low melting point, sublimation point, or decomposition point. As a result, the amount of the ions of the first metal element generated can be stabilized and increased simultaneously.

The first material may include a metal or a halide containing the first metal element. When the first metal element is gallium (Ga), the metal containing the first metal element is pure gallium or an alloy containing gallium. When the first metal element is gallium (Ga), the halide containing the first metal element is, for example, gallium fluoride (for example, GaF₃, melting point 800° C.), gallium chloride (for example, GaCl₃, melting point 78° C.), gallium bromide (for example, GaBr₃, melting point 122° C.), or gallium iodide (for example, GaI₃, melting point 212° C.). As the first material, a material where the metal containing the first metal element and the halide containing the first metal element are mixed may be used.

The second material may include an oxide, a nitride, or a carbide containing the first metal element. When the first metal element is gallium (Ga), the oxide, the nitride, or the carbide containing the first metal element is gallium oxide (for example, Ga₂O₃, melting point 1740° C.) or gallium nitride (for example, GaN, sublimation point 800° C.).

The second material may include an oxide, a nitride, or a carbide containing an element different from the first metal element. Examples of the second material include silicon oxide (for example, SiO₂, melting point 1650° C.), silicon nitride (for example, Si₃N₄, decomposition point 1900° C.), and silicon carbide (for example, SiC, melting point 2730° C.).

The second material may include an oxide, a nitride, or a carbide containing the second metal element different from the first metal element. The second metal element may be a rare earth metal, a transition metal, or a semimetal. When the first metal element is gallium (Ga), the second metal element is, for example, aluminum (Al), indium (In), antimony (Sb), tin (Sn), magnesium (Mg), copper (Cu), zirconium (Zr), hafnium (Hf), ruthenium (Ru), rhodium (Rh), palladium (Pd), lanthanum (La), gadolinium (Gd), terbium (Tb), dysprosium (Dy), erbium (Er), or ytterbium (Yb), but is not limited thereto. Examples of the second material include aluminum oxide (for example, Al₂O₃, melting point 2072° C.), aluminum nitride (for example, AlN, melting point 2977° C.), aluminum carbide (for example, Al₄C₃, melting point 2200° C.), indium oxide (for example, In₂O₃, melting point 1910° C.), indium nitride (for example, InN, melting point 1100° C.), antimony oxide (for example, Sb₂O₃, melting point 656° C.), tin oxide (for example, SnO₂, melting point 1630° C.), magnesium oxide (for example, MgO, melting point 2852° C.), magnesium nitride (for example, Mg₃N₂, decomposition point 1500° C.), copper oxide (for example, CuO, melting point 1201° C.), zirconium oxide (for example, ZrO₂, melting point 2715° C.), zirconium nitride (for example, ZrN, melting point 2980° C.), zirconium carbide (for example, ZrC, melting point 3540° C.), hafnium oxide (for example, HfO₂, melting point 2758° C.), hafnium nitride (for example, HfN, melting point 3305° C.), hafnium carbide (for example, HfC, melting point 3890° C.), ruthenium oxide (for example, RuO₂, sublimation point 1200° C.), rhodium oxide (for example, Rh₂O₃, decomposition point 1150° C.), palladium oxide (PdO, melting point 750° C.), lanthanum oxide (for example, La₂O₃, melting point 2315° C.), gadolinium oxide (for example, Gd₂O₃, melting point 2420° C.), terbium oxide (for example, Tb₂O₃, melting point 2410° C.), dysprosium oxide (for example, Dy₂O₃, melting point 2408° C.), erbium oxide (for example, Er₂O₃, melting point 2344° C.), and ytterbium oxide (for example, Yb₂O₃, melting point 2355° C.).

The second material may contain a metal containing the second metal element different from the first metal element. Examples of the second material include copper (for example, pure copper, melting point 1085° C.), metal zirconium (for example, pure zirconium, melting point 1855° C.), metal hafnium (for example, pure hafnium, melting point 2222° C.), metal ruthenium (for example, pure ruthenium, melting point 2334° C.), metal rhodium (for example, pure rhodium, melting point 1964° C.), metal palladium (for example, pure palladium, melting point 1555° C.), metal lanthanum (for example, pure lanthanum, melting point 920° C.), metal gadolinium (for example, pure gadolinium, melting point 1312° C.), metal terbium (for example, pure terbium, melting point 1356° C.), metal dysprosium (for example, pure dysprosium, melting point 1407° C.), metal erbium (for example, pure erbium, melting point 1529° C.), metal ytterbium (for example, pure ytterbium, melting point 824° C.), and an alloy thereof. The second material may include a metal or an alloy thereof, for example, metal tungsten (for example, pure tungsten, melting point 3387° C.), metal tantalum (for example, pure tantalum, melting point 2996° C.), metal molybdenum (for example, pure molybdenum, melting point 2610° C.), or metal niobium (for example, pure niobium, melting point 2468° C.).

The second material may contain glass or a ceramic. The second material may be, for example, a single substance of the oxide, the nitride, or the carbide described above, may be a mixture of the oxide, the nitride, or the carbide described above, or may contain any non-metal inorganic material different from the oxide, the nitride, or the carbide described above.

The solid source material 90 may further contain a third material that is a halide containing an element different from the first metal element. The solid source material 90 may contain the first material that contains the first metal element (for example, Ga) and has a melting point, a sublimation point, or a decomposition point lower than the predetermined operating temperature (for example, 100° C. to 1200° C.), the second material that contains an oxide, a nitride, a carbide, or a metal and has a melting point, a sublimation point, or a decomposition point higher than the predetermined operating temperature (for example, 100° C. to 1200° C.), and the third material that is a halide containing an element different from the first metal element.

The solid source material 90 may include a green compact obtained by compression-molding a powder where the first material, the second material, and the third material are mixed. For example, a powder of the first material, a powder of the second material, and a powder of the third material are prepared, a powder where both of the powders are mixed is produced, and a pressure is applied to the mixed powder to be molded into a pellet form. The molding pressure is not particularly limited and is, for example, 10 MPa or more and 1000 MPa or less, for example, 20 MPa or more and 500 MPa or less, or, for example, 50 MPa or more and 200 MPa or less. During or before compression molding, the powder of the first material, the second material, and the third material may be cooled to a temperature of room temperature (for example, 20° C.) or lower. The average particle size of the powder of the first material, the second material, or the third material is not particularly limited and is, for example, 0.1 μm or more and 2 mm or less, for example, 1 μm or more and 1 mm or less, or for example, 10 μm or more and 100 μm or less. The size of the molded green compact is not particularly limited and is, for example, 1 mm or more and 50 mm or less, or for example, 5 mm or more and 20 mm or less. The shape of the molded green compact is not particularly limited and may be, for example, a columnar shape, a disk shape, a spherical shape, an ellipsoidal shape, a cubic shape, a rectangular parallelepiped shape, a tablet shape, or an indefinite shape. The solid source material 90 may include only one piece of green compact or multiple pieces of green compact. A ratio W2/W1 between a first weight W1 of the first material and a second weight W2 of the second material in the solid source material 90 is, for example, 0.1 or more and 10 or less, for example, 0.2 or more and 5 or less, or for example, 0.5 or more and 2 or less. A ratio W3/W1 between a first weight W1 of the first material and a third weight W3 of a third material in the solid source material 90 is, for example, 0.1 or more and 10 or less, for example, 0.2 or more and 5 or less, or for example, 0.5 or more and 2 or less.

The third material is preferably a material that reacts with the first metal element in the first material at the predetermined operating temperature to produce a halide of the first metal element. The third material is preferably ammonium halide, and is, for example, ammonium fluoride (NH₄F, melting point 98° C.), ammonium chloride (NH₄Cl, decomposition point 338° C.), ammonium bromide (NH₄Br, sublimation point 452° C.), or ammonium iodide (NH₄I, sublimation point 551° C.). The third material may be a halide of any metal element, for example, a halide of the above-described second metal element or a halide of a metal element different from the second metal element. By producing a halide of the first metal element, the vapor pressure of the vapor containing the first metal element can be increased, and the amount of the ions of the first metal element generated can be increased.

The plasma generating device 70 may supply the vapor containing the first metal element (for example, Ga) from the vapor generating device 60, and may also supply the assist gas from the gas introduction port 82. The plasma generating device 70 may generate a plasma using mixed gas of the vapor supplied from the vapor generating device 60 and the assist gas supplied from the gas introduction port 82. By using the assist gas, the generation of the plasma in the plasma generating chamber 78 can be stabilized as compared to a case where the assist gas is not used. In addition, by adjusting the amount of the assist gas supplied, the plasma density generated in the plasma generating chamber 78 can be adjusted, and the beam current of the ion beam IB extracted from the plasma generating device 70 is easily adjusted. Further, depending on the type of the assist gas, attachment of contamination to an inner surface of the arc chamber 72 can be suppressed, and the lifetime of the plasma generating device 70 can be improved.

The assist gas is made of a simple substance or a compound of an element different from the first metal element (for example, Ga) to be extracted as the ion beam IB. The assist gas is, for example, rare gas, hydrogen compound gas, or halide gas. As the assist gas, for example, nitrogen gas (N₂), neon (Ne), argon (Ar), xenon (Xe), arsine (AsH₃), phosphine (PH₃), boron trifluoride (BF₃), phosphorus trifluoride (PF₃), or arsenic trifluoride (AsF₃) can be used.

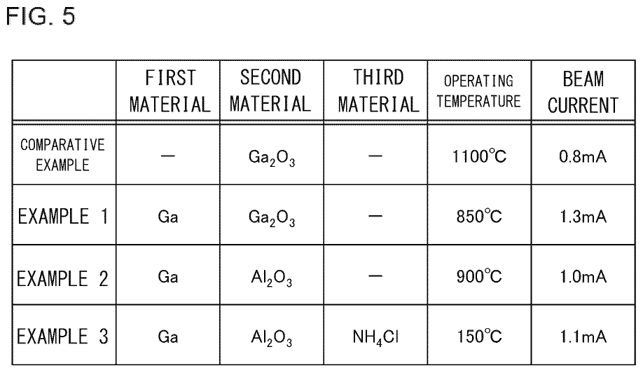

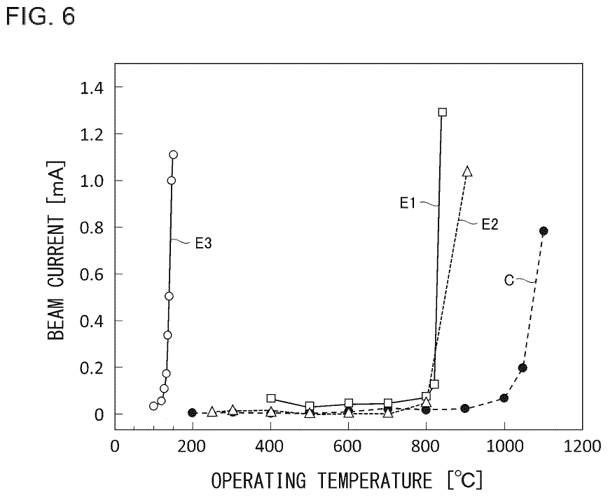

Next, Examples will be described. FIG. 5 is a table illustrating materials and operating temperatures of the solid source materials 90 in Comparative Example and Examples and obtained beam currents. FIG. 6 is a graph illustrating a relationship between the operating temperatures and the beam currents in Comparative Example and Examples.

In Comparative Example, only gallium oxide (Ga₂O₃) was used as the solid source material. A solid material obtained by compression-molding a powder of gallium oxide in a disk shape was disposed in the vapor generating chamber 68, and when the vapor generating chamber 68 was heated at a predetermined operating temperature, the current of ions (monovalent gallium ions) of the first metal element extracted from the plasma generating device 70 was measured. As illustrated in FIG. 6, as the operating temperature increases, the beam current tends to increase. In Comparative Example indicated by a graph C in FIG. 6, when the operating temperature was 1100° C., a gallium ion beam of 0.8 mA was obtained. After stopping the operation, when the inside of the vapor generating chamber 68 was observed, the solid material made of gallium oxide disappeared.

In Example 1, metal gallium (pure gallium) was used as the first material, and gallium oxide (Ga₂O₃) was used as the second material. In Example 1, the solid source material 90 obtained by compression-molding a powder where metal gallium and gallium oxide were mixed in a disk shape was disposed in the vapor generating chamber 68. The ratio (W2/W1) between the first weight W1 of metal gallium and the second weight W2 of gallium oxide was 0.67. Next, when the vapor generating chamber 68 was heated at a predetermined operating temperature, the current of ions (monovalent gallium ions) of the first metal element extracted from the plasma generating device 70 was measured. In Example 1 indicated by a graph E1 in FIG. 6, when the operating temperature was 850° C., a gallium ion beam of 1.3 mA was obtained. It was found that, in Example 1, even when the operating temperature is lower than that of Comparative Example, the amount of gallium ions generated can be increased. After stopping the operation, when the inside of the vapor generating chamber 68 was observed, the green compact mainly made of the second material where the content of the first material was decreased remained, and the disk shape that was equivalent to that before the start of the operation was maintained. The reason for this is presumed to be that, in the vapor generating chamber 68 during the operation, the liquid gallium was held by the second material without flowing, and vaporization of gallium simple substance was suppressed due to the reaction of gallium and gallium oxide.

In Example 2, metal gallium (pure gallium) was used as the first material, and aluminum oxide (Al₂O₃) was used as the second material. In Example 2, the solid source material 90 obtained by compression-molding a powder where metal gallium and aluminum oxide were mixed in a disk shape was disposed in the vapor generating chamber 68. The ratio (W2/W1) between the first weight W1 of metal gallium and the second weight W2 of aluminum oxide was 1.3. In Example 2 indicated by a graph E2 in FIG. 6, when the operating temperature was 900° C., a gallium ion beam of 1.0 mA was obtained. It was found that, in Example 2, even when the operating temperature is lower than that of Comparative Example, the amount of gallium ions generated can be increased. In Example 2, the beam current was lower than that of Example 1. The reason for this is presumed to be that the oxide not containing the first metal element was used as the second material. After stopping the operation, when the inside of the vapor generating chamber 68 was observed, the green compact mainly made of the second material where the content of the first material was decreased remained, and the disk shape that was equivalent to that before the start of the operation was maintained. The reason for this is presumed to be that, in the vapor generating chamber 68 during the operation, the liquid gallium was held by the second material without flowing.

In Example 3, metal gallium (pure gallium) was used as the first material, aluminum oxide (Al₂O₃) was used as the second material, and ammonium chloride (NH₄Cl) was used as the third material. In Example 3, the solid source material 90 obtained by compression-molding a powder where metal gallium, aluminum oxide, and ammonium chloride were mixed in a disk shape was disposed in the vapor generating chamber 68. The ratio (W2/W1) between the first weight W1 of metal gallium and the second weight W2 of aluminum oxide was 1.3, which was the same as that of Example 2. The ratio (W3/W1) between the first weight W1 of metal gallium and the third weight W3 of ammonium chloride was 2. In Example 3 indicated by a graph E3 in FIG. 6, when the operating temperature was 150° C., a gallium ion beam of 1.1 mA was obtained. It was found that, even when the operating temperature is much lower than that of Comparative Example or Examples 1 and 2, gallium ions can be sufficiently generated. It is presumed that, in Example 3, by mixing the third material, the generation of the vapor containing gallium was promoted, and the amount of the gallium ions generated was increased. After stopping the operation, when the inside of the vapor generating chamber 68 was observed, the green compact mainly made of the second material where the content of the first material or the third material was decreased remained, and the disk shape that was equivalent to that before the start of the operation was maintained. The reason for this is presumed to be that, in the vapor generating chamber 68 during the operation, the liquid gallium was held by the second material without flowing, and vaporization of gallium simple substance was suppressed due to the reaction of gallium and ammonium chloride.

From the above, by using the first material having a melting point, a sublimation point, or a decomposition point lower than the operating temperature, the amount of the ions generated can be increased. By using the second material having a melting point, a sublimation point, or a decomposition point higher than the operating temperature in combination, fluidization of the first material can be suppressed during the operation, and the amount of the ions generated can be stabilized. In addition, by further using the third material that is a halide in combination, vaporization as the compound containing the first metal element can be promoted, and the amount of the ions generated can be increased even at a lower operating temperature. In the present embodiment, the amount of the metal ions generated can be stabilized and increased simultaneously, and a metal ion beam having a high beam current can be stably provided.

In the above-described embodiment, the case where the first metal element is gallium (Ga) is described. In another embodiment, the first metal element does not need to be gallium. The first metal element may be, for example, aluminum (Al), indium (In), antimony (Sb), tin (Sn), magnesium (Mg), copper (Cu), zirconium (Zr), hafnium (Hf), ruthenium (Ru), rhodium (Rh), palladium (Pd), lanthanum (La), gadolinium (Gd), terbium (Tb), dysprosium (Dy), erbium (Er), or ytterbium (Yb).

The first material may contain, for example, metal gallium (for example, pure gallium, melting point 30° C.), metal aluminum (for example, pure aluminum, melting point 660° C.), metal indium (for example, pure indium, melting point 157° C.), metal antimony (for example, pure antimony, melting point 631° C.), metal tin (for example, pure tin, melting point 232° C.), metal magnesium (for example, pure magnesium, melting point 650° C.), copper (for example, pure copper, melting point 1085° C.), metal lanthanum (for example, pure lanthanum, melting point 920° C.), or metal ytterbium (for example, pure ytterbium, melting point 824° C.).

The first material may contain a halide of the first metal element. The first material may include gallium fluoride (for example, GaF₃, melting point 800° C.), gallium chloride (for example, GaCl₃, melting point 78° C.), gallium bromide (for example, GaBr₃, melting point 122° C.), gallium iodide (for example, GaI₃, melting point 212° C.), aluminum fluoride (for example, AlF₃, melting point 1040° C.), aluminum chloride (for example, AlCl₃, sublimation point 180° C.), aluminum bromide (for example, AlBr₃, melting point 98° C.), aluminum iodide (for example, AlI₃, melting point 191° C.), indium chloride (for example, InCl₃, melting point 586° C.), indium bromide (for example, InBr₃, sublimation point 436° C.), indium iodide (for example, InI₃, melting point 210° C.), antimony fluoride (for example, SbF₃, melting point 292° C.), antimony chloride (for example, SbCl₃, melting point 73° C.), antimony bromide (for example, SbBr₃, melting point 97° C.), antimony iodide (for example, SbI₃, melting point 171° C.), tin fluoride (for example, SnF₂, melting point 215° C.), tin chloride (for example, SnCl₂, melting point 247° C.), tin bromide (for example, SnBr₂, melting point 215° C.), tin iodide (for example, SnI₂, melting point 320° C.), magnesium chloride (for example, MgCl₂, melting point 714° C.), magnesium bromide (for example, MgBr₂, melting point 711° C.), magnesium iodide (for example, Mgl2, melting point 637° C.), copper fluoride (for example, CuF₂, melting point 836° C.), copper chloride (for example, CuCl₂, melting point 498° C.), copper bromide (for example, CuBr₂, melting point 498° C.), copper iodide (for example, CuI, melting point 605° C.), zirconium fluoride (for example, ZrF₄, melting point 640° C.), zirconium chloride (for example, ZrCl₄, sublimation point 331° C.), zirconium bromide (for example, ZrBr₄, sublimation point 360° C.), zirconium iodide (for example, Zr14, sublimation point 431° C.), hafnium fluoride (for example, HfF₄, melting point 310° C.), hafnium chloride (for example, HfCl4, sublimation point 316° C.), hafnium bromide (for example, HfBr₄, melting point 220° C.), hafnium iodide (HfI₄, sublimation point 394° C.), ruthenium fluoride (for example, RuF₅, melting point 87° C.), ruthenium chloride (for example, RuCl₃, decomposition point 500° C.), ruthenium bromide (for example, RuBr₃, decomposition point 400° C.), ruthenium iodide (for example, RuI₃, decomposition point 590° C.), rhodium fluoride (for example, RhF₆, melting point 70° C.), rhodium chloride (for example, RhCl₃, decomposition point 450° C.), palladium fluoride (for example, PdF₂, melting point 952° C.), palladium chloride (for example, PdCl₂, decomposition point 675° C.), palladium iodide (for example, PdI₂, decomposition point 350° C.), lanthanum chloride (for example, LaCl₃, melting point 860° C.), lanthanum bromide (for example, LaBr₃, melting point 783° C.), lanthanum iodide (for example, LaI₃, melting point 766° C.), gadolinium chloride (for example, GdCl₃, melting point 628° C.), gadolinium bromide (for example, GdBr₃, melting point 770° C.), gadolinium iodide (for example, GdI₃, melting point 926° C.), terbium chloride (for example, TbCl₃, sublimation point 180° C.), terbium bromide (for example, TbBr₃, melting point 827° C.), terbium iodide (for example, TbI₃, melting point 957° C.), dysprosium chloride (for example, DyCl₃, melting point 647° C.), dysprosium iodide (for example, DyI₂, melting point 659° C.), erbium chloride (for example, ErCl₃, melting point 774° C.), erbium bromide (for example, ErBr₃, melting point 923° C.), erbium iodide (for example, ErI₃, melting point 1020° C.), ytterbium chloride (for example, YbCl₃, melting point 703° C.), ytterbium bromide (for example, YbBr₃, melting point 904° C.), or ytterbium iodide (for example, Ybl3, melting point 772° C.). For example, when the melting point of the metal containing the first metal element (for example, a metal simple substance of the first metal element) is high, a halide of the first metal element can be used.

The solid source material 90 may contain any of the above-described first material or any of the above-described second material. For example, the first material may contain a metal containing the first metal element, and the second material may contain an oxide, a nitride, or a carbide containing the first metal element. For example, the first material may contain a metal containing the first metal element, and the second material may contain an oxide, a nitride, or a carbide containing an element different from the first metal element. For example, the first material may contain a metal containing the first metal element, and the second material may contain an oxide, a nitride, or a carbide containing the second metal element different from the first metal element. For example, the first material may contain a metal containing the first metal element, and the second material may contain a metal containing the second metal element different from the first metal element. For example, the first material may contain a halide of the first metal element, and the second material may contain a metal containing the first metal element. For example, the first material may contain a halide of the first metal element, and the second material may contain a metal containing the second metal element different from the first metal element. In this regard, the solid source material 90 may further contain any of the above-described third material.

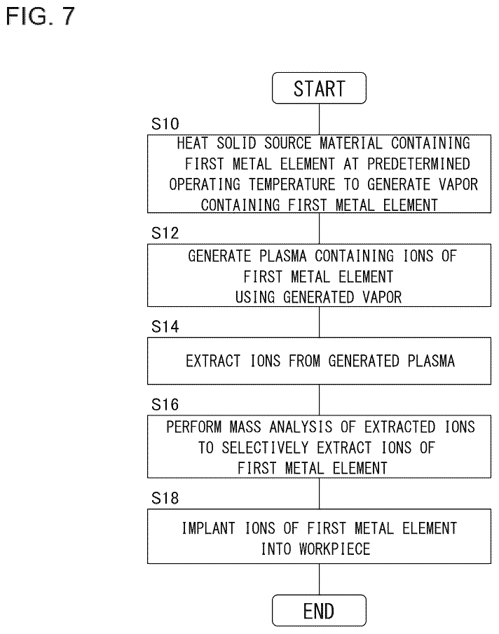

FIG. 7 is a flowchart illustrating an example of the ion implantation method according to the embodiment. The vapor generating device 60 heats the solid source material 90 containing the first metal element at the predetermined operating temperature to generate a vapor containing the first metal element (S10). Here, the solid source material 90 contains the first material that contains the first metal element and has a melting point, a sublimation point, or a decomposition point lower than the predetermined operating temperature, and the second material that contains an oxide, a nitride, a carbide, or a metal and has a melting point, a sublimation point, or a decomposition point higher than the predetermined operating temperature. The plasma generating device 70 generates the plasma P containing ions of the first metal element using the vapor generated by the vapor generating device 60 (S12). The extraction electrode 88 extracts the ions from the plasma P generated by the plasma generating device 70 (S14). The mass analyzer 20 performs mass analysis of the ions extracted by the extraction electrode 88 to selectively extract ions of the first metal element (S16). As a result, the ion beam of the first metal element is generated. The ions or the ion beam of the first metal element is implanted into the workpiece W in the implantation processing chamber 16 (S18).

Although the present disclosure has been described above with reference to each of the above-described embodiments, the present disclosure is not limited to each of the above-described embodiments and appropriate combinations and replacements of the configuration of the respective embodiments described above are included in the present disclosure. Further, it is also possible to rearrange the combination in each of the above-described embodiments or the order of processing as appropriate based on the knowledge of those skilled in the art, or to add modifications such as various design changes to the embodiment. The scope of the present disclosure may also include the embodiment to which such a modification is added.

### INDUSTRIAL APPLICABILITY

According to the present disclosure, the amount of metal ions generated using a vapor obtained by heating a solid source material can be stabilized and increased.

It should be understood that the invention is not limited to the above-described embodiment, but may be modified into various forms on the basis of the spirit of the invention. Additionally, the modifications are included in the scope of the invention.

What is claimed is:

1. An ion implantation method comprising:
heating a solid source material containing a first metal element at a predetermined operating temperature to generate a vapor containing the first metal element;
generating a plasma containing ions of the first metal element using the vapor; and
implanting the ions of the first metal element obtained from the plasma into a workpiece,
wherein the solid source material contains
a first material that contains the first metal element and has a melting point, a sublimation point, or a decomposition point lower than the operating temperature, and
a second material that contains an oxide, a nitride, a carbide, or a metal and has a melting point, a sublimation point, or a decomposition point higher than the operating temperature.

2. The ion implantation method according to claim 1,
wherein the first material contains a metal or a halide containing the first metal element.

3. The ion implantation method according to claim 2,
wherein the second material contains an oxide, a nitride, or a carbide containing the first metal element.

4. The ion implantation method according to claim 2,
wherein the second material contains an oxide, a nitride, or a carbide containing an element different from the first metal element.

5. The ion implantation method according to claim 1,
wherein the second material contains an oxide, a nitride, a carbide, or a metal containing a second metal element different from the first metal element.

6. The ion implantation method according to claim 1,
wherein the first material contains a halide of the first metal element, and
the second material contains a metal containing the first metal element or a metal containing a second metal element different from the first metal element.

7. The ion implantation method according to claim 1,
wherein the second material contains glass or a ceramic.

8. The ion implantation method according to claim 1,
wherein the first metal element is Ga, Al, In, Sb, Sn, Mg, Cu, Zr, Hf, Ru, Rh, Pd, La, Gd, Tb, Dy, Er, or Yb.

9. The ion implantation method according to claim 1,
wherein a ratio W2/W1 between a first weight W1 of the first material and a second weight W2 of the second material in the solid source material is 0.1 or more and 10 or less.

10. The ion implantation method according to claim 1,
wherein the solid source material contains a green compact obtained by compression-molding a powder where the first material and the second material are mixed.

11. The ion implantation method according to claim 10,
wherein a size of the green compact is 1 mm or more and 50 mm or less.

12. The ion implantation method according to claim 10,
wherein an average particle size of the powder is 1 μm or more and 1 mm or less.

13. The ion implantation method according to claim 1,
wherein the solid source material further contains a third material that is a halide containing an element different from the first metal element.

14. The ion implantation method according to claim 13,
wherein the third material is ammonium halide.

15. The ion implantation method according to claim 13,
wherein the solid source material contains a green compact obtained by compression-molding a powder where the first material, the second material, and the third material are mixed.

16. The ion implantation method according to claim 13,
wherein a ratio W3/W1 between a first weight W1 of the first material and a third weight W3 of the third material in the solid source material is 0.1 or more and 10 or less.

17. The ion implantation method according to claim 1,
wherein the operating temperature is 100° C. or higher and 1200° C. or lower.

18. The ion implantation method according to claim 1, further comprising mixing assist gas with the vapor,
wherein the plasma is generated using mixed gas of the vapor and the assist gas.

19. The ion implantation method according to claim 1, further comprising:
extracting ions from the generated plasma; and
performing mass analysis of the extracted ions to selectively extract the ions of the first metal element,
wherein a beam current of the ions of the first metal element implanted into the workpiece is 0.1 mA or more and 20 mA or less.

20. A solid source material that is heated at a predetermined operating temperature for generating ions of a first metal element to be implanted into a workpiece, the solid source material comprising:
a first material that contains the first metal element and has a melting point, a sublimation point, or a decomposition point lower than the operating temperature; and
a second material that contains an oxide, a nitride, a carbide, or a metal and has a melting point, a sublimation point, or a decomposition point higher than the operating temperature.
